(19) United States
(12) Patent Application Publication
(10) Pub. No.: US 2018/0096823 A1
(43) Pub. Date: Apr. 5, 2018

(54) LARGE AREA ENERGETIC ION SOURCE

(71) Applicant: Intevac, Inc., Santa Clara, CA (US)

(72) Inventors: Terry Bluck, Santa Clara, CA (US); Babak Adibi, Los Altos, CA (US)

(21) Appl. No.: 15/721,534

(22) Filed: Sep. 29, 2017

Related U.S. Application Data
(60) Provisional application No. 62/402,220, filed on Sep. 30, 2016.

(51) Int. Cl. H01J 37/32

(52) U.S. Cl. CPC H01J 37/32174; H01J 37/32779; H01J 2237/3365; H01J 37/32568; H01J 2237/3344; H01J 37/32422

(57) ABSTRACT

An RF antenna system for a plasma chamber comprises an RF input coupling a trunk to an RO power supply; two main branches electrically connected to the main trunk, each of the two main branches coupled to a plurality of rod antennas; a plurality of tuning devices, each provided between one of the rod antennas and the corresponding main branch.

### RELATED APPLICATION

This Application claims priority benefit from U.S. Provisional Application No. 62/402,220, filed on Sep. 30, 2016, the disclosure of which is incorporated herein by reference in its entirety.

### BACKGROUND

### 1. Field

The disclosed invention relates to plasma chamber and, more specifically, to architecture for applying RF power to large area plasma chamber.

### 2. Related Art

Plasma chambers are well known in the art. Plasma may be sustained inside the chamber by the application of RF power. In some chambers, the RF power is applied using an RF antenna placed over a dielectric window, e.g., a quartz ceiling. Such chambers are sometimes referred to an inductively-coupled plasma chambers. Traditionally these chambers had circular construction for processing round substrates, e.g., up to 300 mm semiconductor wafers.

Recently inductively plasma chambers have been adopted for processing square or rectangular substrates, in addition to circular substrates. Such design can be used, e.g., for ion implant, etching or deposition on substrates, e.g., solar cells and touchscreen displays. Solar cells and touchscreen display substrates are square or rectangular, not round. Also, to increase throughput some systems transfer the substrates on conveyor belts and perform plasma processing as the substrate pass in the processing chamber. For such chambers the processing window is relatively large and is rectangle. However, because of circular symmetry it is much simpler to control plasma uniformity in a round chamber than in a square or rectangular chamber.

Therefore, there a need in the art for improved plasma uniformity, especially in non-round plasma chambers.

### SUMMARY

The following summary is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

Embodiments disclosed herein describe solutions to the issues highlighted above. The embodiments enable sustaining plasma in a non-circular chamber while controlling the uniformity of the plasma over the area of the chamber.

Various embodiments and features are designed in order to perform the plasma processing in a uniform manner across the entire surface of the substrate(s). The disclosed solutions enable continuous processing of substrates transported on a conveyor. The substrates may be of any shape.

According to disclosed embodiments, an antenna system is provided for sustaining uniform plasma inside a plasma chamber. The antenna system splits into a plurality of branches, each branch having individual tuning device, thus enabling control of the distribution of RF power onto the branches.

According to disclosed aspects an RF antenna system for a plasma chamber is provided. The antenna comprises an RF input coupling a trunk to an RF power supply; two main branches are electrically connected to the main trunk, each of the two main branches coupled to a plurality of rod antennas; a plurality of tuning devices, each provided between one of the rod antennas and the corresponding main branch.

According to further aspects an plasma chamber is provided, comprising: a vacuum enclosure having sidewalls and ceiling; an RF antenna system having branches extending into the enclosure and positioned below the ceiling; each of the branches comprising a conductor inserted within a dielectric tube, wherein all of the conductors are electrically coupled to an RF power source through a variable load element at one end, and to ground at an opposite end. In one embodiment the enclosure comprises a rectangular enclosure and the branches are oriented across the narrower side of the rectangular enclosure. In one embodiment the branches interlace such that the coupling to the RF power source and the ground alternate. In disclosed embodiment magnets are provided over the ceiling for plasma shaping or improving plasma uniformity. The magnets may be aligned with the branches.

According to further aspects an RF antenna for a plasma chamber is provided, comprising: a first set of conductive rods having an input end on a side of a first sidewall and a grounded end on a side of an opposite sidewall; a second set of conductive rods having a grounded end on the side of the first sidewall and an input end on the side of the opposite sidewall, wherein the first set of conductive rods and the second set of conductive rods are arranged in an interlaced manner, such that each of the conductive rods of the first set of conductive rods is immediately adjacent a conductive rod of the second set of conductive rods, and every two consecutive conductive rods of the first set of conductive rods have one conductive rod of the second set of conductive rods in between them; a first set of variable tuning elements, each connected to the input end of a respective one of the first set of conductive rods; a second set of variable tuning elements, each connected to the input end of a respective one of the second set of conductive rods; a first RF branch connected to the first set of variable tuning elements; a second RF branch connected to the second set of variable tuning elements, wherein the first RF branch and the second RF branch are commonly couple to an RF source.

Other features and aspects are described in the following Detailed Description with reference to the Drawings.

### BRIEF DESCRIPTION OF THE DRAWINGS

The accompanying drawings, which are incorporated in and constitute a part of this specification, exemplify the embodiments of the present invention and, together with the description, serve to explain and illustrate principles of the invention. The drawings are intended to illustrate major features of the exemplary embodiments in a diagrammatic manner. The drawings are not intended to depict every feature of actual embodiments nor relative dimensions of the depicted elements, and are not drawn to scale.

FIG. 1 is a top view diagram of an antenna system for sustaining energetic plasma over a large area, according to disclosed embodiment.

FIG. 2 is an illustration of a plasma chamber utilizing the inventive antenna system, according to disclosed embodiment.

FIG. 3 is an illustration of another plasma chamber utilizing the inventive antenna system, according to disclosed embodiment.

### DETAILED DESCRIPTION

Embodiments of the inventive antenna system and method will now be described with reference to the drawings. Different embodiments or their combinations may be used for different applications or to achieve different benefits. Depending on the outcome sought to be achieved, different features disclosed herein may be utilized partially or to their fullest, alone or in combination with other features, balancing advantages with requirements and constraints. Therefore, certain benefits will be highlighted with reference to different embodiments, but are not limited to the disclosed embodiments. That is, the features disclosed herein are not limited to the embodiment within which they are described, but may be “mixed and matched” with other features and incorporated in other embodiments.

Various embodiments and features described below are designed in order to enable control of the plasma uniformity over a large area. This enables plasma processing of large substrates, or processing of multiple substrates, especially when the substrates travel during processing. The antenna system is especially beneficial when the processing window is rectangular. In such implementations, it is beneficial although not necessary, to arrange the rods of the antenna elements (also referred to as rods) across the short side of the rectangular window.

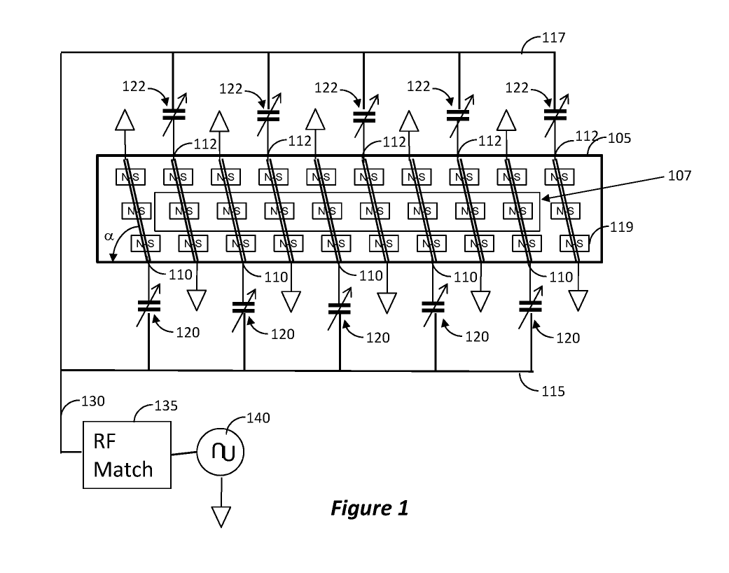

FIG. 1 illustrates a top view of a general architecture of a system for RF antenna, according to one embodiment. The system in this particular embodiment is designed to be placed across the short side of a rectangular plasma enclosure. The design is made to compensate for voltage drop that normally occurs over the length of the antenna. The method implemented in disclosed embodiments is to split the RF signal into a plurality of antennas, and to control the percentage of RF power applied to each antenna. Also, the antennas are arranged such that the voltage drop of one antenna is countered by opposite voltage drop of a neighboring antenna. Thus on average the plasma does not “see” a voltage drop.

As illustrated in FIG. 1, the plasma enclosure is indicated by rectangle 105, identifying the sidewalls of the vacuum chamber. In this particular example, processing is performed via a window 107, which is also rectangular, but having smaller dimensions than the chamber sidewalls 105. The RF antenna comprises a first set of conductive rods 110 and a second set of conductive rods 112. Each of the first set of conductive rods 110 is coupled to a first main branch 115 via a respective tuning device 120. Each of the second set of conductive rods 112 is coupled to a second main branch 117 via a respective tuning device 122. Each of the tuning devices may be adjusted so as to change the amount of power applied to the corresponding conductive rod. In the embodiment shown in FIG. 1, each tuning device 120 and 122 is a variable capacitor. The other end of each rod is coupled to ground or common potential. The two main branches 115 and 117 are connected to the main trunk 130. The main trunk 130 is coupled to the RF power source 140 via a matching circuit 135.

Following the RF path in FIG. 1, the power from the RF match circuit 135 is applied to the main trunk 130. Then it splits into the two main branches, 115 and 117. From main branch 115 the power is then distributed to conductive rods 110 at proportions tuned using tuning elements 120. Similarly, the power from main branch 117 is distributed to conductive rods 112 at proportions tuned using tuning elements 122. As shown in FIG. 1, the conductive rods 110 are interlaced with conductive rods 112. That is, the conductive rods 110 from the first set are arranged alternatingly with rods 112 from the second set, such that there are no two successive conductive rods from one set. In this manner, the voltage drop in one conductive rod from one set is countered by the opposite voltage drop from the next conductive rod—which is from the other set.

In this embodiment plasma uniformity is also enhanced by the geometrical orientation of the conductive rods. Specifically, as can be seen in FIG. 1, each of the conductive rods makes a non-normal or acute angle α to the sides of the rectangular chamber wall 105. In the example of FIG. 1, any two conductive rods form a parallelogram with the sides of the camber. Also, it should be mentioned that in this example all of the conductive rods are provided on the same plane.

Another feature disclosed in FIG. 1 is the provision of magnets over the conductive rods. The number of magnets provided over each conductive rod may vary, but in the example of FIG. 1 three magnets 119 are provided over each conductive rod. The magnets enhance the plasma density.

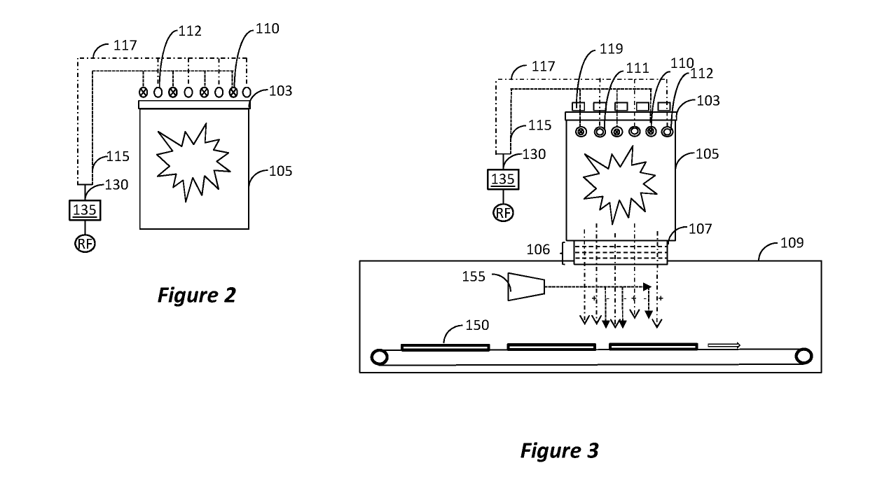

FIG. 2 illustrates a side view of a plasma processing chamber, utilizing the antenna arrangement such as that shown in FIG. 1. As before, the enclosure 105 may be rectangular. It has a ceiling 103 that is made of material that is permeable to RF radiation, e.g., dielectric material such as ceramic. The conductive rods 110 are shown with circled-x meaning voltage drop is in the direction away from the reader and into the page, while conductive rods 112 are shown as empty circles, meaning the voltage drop is I a direction towards the reader and out of the page. In FIG. 2 branch 115 is shown in broken line and branch 117 is shown in dot-dash line merely to assist the reader in distinguishing between them.

FIG. 3, illustrates an embodiment for a plasma processing system, in this example an etcher or an ion implanter, having an RF antenna that enables control over the uniformity of the plasma over a large area. In this example the enclosure 105 of the plasma chamber is square or rectangular, having ceiling 103 and processing window 107. The process window is open to the processing chamber 109, thus enabling ions from the plasma chamber to travel to the processing chamber 109. To facilitate extracting ions from the plasma and accelerating the ions so as to cause the ions to reach the substrates 150, a series of grids 106 are positioned in the processing window 107. In this example three grids are used: a positively biased extraction grid for extracting ions from the plasma, a negatively biased suppression grid, preventing electrons from exiting the plasma chamber, and a grounded grid. The extracted ions may be implanted into the substrates 105, may be deposited on top of substrates 105, or may be used to etch the surface of substrates 105.

In some embodiments, the processing chamber 109 may include a plasma bridge neutralizer 155. A hot-filament, plasma-bridge, or hollow-cathode type of plasma bridge neutralizer may be used to introduce electrons into the processing chamber, such that the electrons (shown in broken lines) may neutralize the positive ions (shown in dash-dot lines) extracted from the plasma. In this example, since a broad ion beam is generated, the density of electrons introduced into the beam may approximately equal the density of ions, so as to generate “space-charge neutralization”. By introducing the electrons into the ion beam, charge build-up on the substrate 150 is prevented. Using the optional plasma bridge neutralizer 155 enables using the neutralized ions to etch the substrates 150.

The example of FIG. 3 enables sustaining high density plasma by placing the antenna conductive rods inside the enclosure 105, below the ceiling 103. To enable such a construction, the conductive rods 110 and 112 are inserted inside quartz tubes 111. The quartz tubes 111 protect the conductive rods 110 and 112 from the plasma, while being permeable to the RF radiation to sustain the plasma. The arrangement of the rods can be interlaced, similar to what as described with respect to FIG. 1. Additionally, if even more dense plasma is required, magnets 119 may be provided over the ceiling 103, similar to what is shown with respect to FIG. 1.

The embodiment of FIG. 3 provides a plasma system comprising: a plasma chamber enclosure having a ceiling and a floor. A plurality of quartz tubes are provided inside the plasma chamber enclosure, below the ceiling, and traversing the plasma chamber enclosure from one side to the opposite side of the plasma chamber enclosure. A plurality of conductive rods are inserted, one in each of the quartz tubes. A plurality of variable tuning device are connected, each to a respective one of the conductive rods, wherein the variable tuning devices are connected to every other conductive rod on the one side of the plasma chamber enclosure and to every other conductive rod on the opposite side of the plasma chamber enclosure, in an interlaced manner. A first RF branch is connected to the variable tuning devices connected on the one side, while a second RF branch is connected to the variable tuning devices on the opposite side. The first and second RF branches are commonly connected to a main RF trunk. In some embodiments, all of the quartz tubes are positioned at a non-normal acute angle to sidewall of the plasma chamber enclosure. When the plasma chamber enclosure is square or rectangular, every two quartz tubes form a parallelogram with two opposite sidewalls of the plasma chamber enclosure. In some embodiments at least one magnet is provided above the ceiling over each of the quartz tubes.

Various embodiments were described above, wherein each embodiment is described with respect to certain features and elements. However, it should be understood that features and elements from one embodiment may be used in conjunction with other features and elements of other embodiments, and the description is intended to cover such possibilities, albeit not all permutations are described explicitly so as to avoid clutter.

It should be understood that processes and techniques described herein are not inherently related to any particular apparatus and may be implemented by any suitable combination of components. Further, various types of general purpose devices may be used in accordance with the teachings described herein. The present invention has been described in relation to particular examples, which are intended in all respects to be illustrative rather than restrictive. Those skilled in the art will appreciate that many different combinations will be suitable for practicing the present invention.

Moreover, other implementations of the invention will be apparent to those skilled in the art from consideration of the specification and practice of the invention disclosed herein. Various aspects and/or components of the described embodiments may be used singly or in any combination. It is intended that the specification and examples be considered as exemplary only, with a true scope and spirit of the invention being indicated by the following claims.

1. An RF antenna for a plasma chamber, comprising:
a first set of conductive rods having an input end on a side of a first sidewall of the plasma chamber and a grounded end on a side of an opposite sidewall of the plasma chamber;
a second set of conductive rods having a grounded end on a side of the first sidewall and an input end on a side of the opposite sidewall, wherein the first set of conductive rods and the second set of conductive rods are arranged in an interlaced manner;
a first set of variable tuning elements, each connected to the input end of a respective one of the first set of conductive rods;
a second set of variable tuning elements, each connected to the input end of a respective one of the second set of conductive rods;
a first RF branch connected to the first set of variable tuning elements;
a second RF branch connected to the second set of variable tuning elements, wherein the first RF branch and the second RF branch are commonly couple to an RF source.

2. The RF antenna of claim 1, further comprising a plurality of quartz tubes and wherein each of the conductive rods is inserted in one of the quartz tubes.

3. The RF antenna of claim 1, further comprising a plurality of magnets, each configured to be positioned over one of the conductive rods.

4. The RF antenna of claim 1, wherein each of the variable tuning elements comprises a variable capacitor.

5. The RF antenna of claim 1, wherein all of the conductive rods are arranged parallel to each other, and any two of the conductive rods define a parallelogram with the first sidewall and the opposite sidewall of the plasma chamber.

6. A plasma chamber, comprising:
a chamber enclosure having a first sidewall, a second sidewall opposite the first sidewall, a ceiling, and a floor; and,
an RF antenna;
wherein the RF antenna comprises:
a first set of conductive rods having an input end on a side of the first sidewall and a grounded end on a side of the second sidewall;
a second set of conductive rods having a grounded end on a side of the first sidewall and an input end on a side of the second sidewall, wherein the first set of conductive rods and the second set of conductive rods are arranged in an interlaced manner;
a first set of variable tuning elements, each connected to the input end of a respective one of the first set of conductive rods;
a second set of variable tuning elements, each connected to the input end of a respective one of the second set of conductive rods;
a first RF branch connected to the first set of variable tuning elements;
a second RF branch connected to the second set of variable tuning elements, wherein the first RF branch and the second RF branch are commonly couple to an RF source.

7. The plasma chamber of claim 6, wherein the ceiling comprises a dielectric material and wherein the first set of conductive rods and the second set of conductive rods are provided over the ceiling.

8. The plasma chamber of claim 6, further comprising a plurality of quartz tubes, each extending from the first sidewall to the second sidewall below the ceiling, and wherein each of the quartz tubes houses one of the conductive rods.

9. The plasma chamber of claim 8, further comprising a plurality of magnets situated over the ceiling.

10. The plasma chamber of claim 9, wherein several magnets of the plurality of magnets are arranged linearly above each of the quartz tubes.

11. The plasma chamber of claim 8, wherein each of the plurality of quartz tube is positioned at an acute angle to the first sidewall.

12. The plasma chamber of claim 8, wherein any two of the quartz tubes define a parallelogram with the first and second sidewalls.

13. The plasma chamber of claim 8, wherein the plurality of quartz tube is positioned at a single plane.

14. The plasma chamber of claim 6, wherein each of the variable tuning elements comprises a variable capacitor.

15. The plasma chamber of claim 6, further comprising:
a processing chamber positioned below the plasma chamber;
a window provided in the floor of the plasma chamber and connecting to the processing chamber;
extraction grids configured to extract ions from the plasma and accelerate the ions towards substrates in the processing chamber, through the window.

16. The system of claim 15, further comprising a conveyor positioned inside the processing chamber and transporting substrates under the window.

17. A plasma processing system, comprising:
a plasma chamber enclosure having a ceiling and a floor;
a plurality of quartz tubes provided inside the plasma chamber enclosure, below the ceiling and traversing the plasma chamber enclosure from one side to the opposite side of the plasma chamber enclosure;
a plurality of conductive rods inserted one in each of the quartz tubes;
a plurality of variable tuning device, each connected to a respective one of the conductive rods, wherein the variable tuning devices are connected to every other conductive rod on the one side of the plasma chamber enclosure and to every other conductive rod on the opposite side of the plasma chamber enclosure, in an interlaced manner;
a first RF branch connected to the variable tuning devices connected on the one side;
a second RF branch connected to the variable tuning devices on the opposite side wherein the first and second RF branches are commonly connected to a main RF trunk.

18. The system of claim 17, wherein each of the plurality of quartz tubes is positioned at an acute, non-normal angle to the one wall.

19. The system of claim 18, further comprising a plurality of magnets provided above the ceiling.

20. The system of claim 17, further comprising a processing chamber provided below the plasma chamber, and a window enabling ions to travel from the plasma chamber to the processing chamber.

21. The system of claim 20, further comprising a grid arrangement positioned in the window, the grid arrangement comprising: an extraction grid, a suppression grid, and a ground grid.
